(19) United States
(12) Patent Application Publication
(10) Pub. No.: US 2012/0329257 A1
(43) Pub. Date: Dec. 27, 2012

(54) METHOD FOR MANUFACTURING SEMICONDUCTOR DEVICE

(75) Inventor: Haruo NAKAZAWA, Matsumoto-city (JP)

(73) Assignee: FUJI ELECTRIC CO., LTD., Kawasaki (JP)

(21) Appl. No.: 13/566,472

(22) Filed: Aug. 3, 2012

Related U.S. Application Data
(63) Continuation of application No. PCT/JP2011/051625, filed on Jan. 27, 2011.

(30) Foreign Application Priority Data
Feb. 4, 2010 (JP) 2010-023378

(51) Int. Cl. H01L 21/265

(52) U.S. Cl. 438/530; 257/E21.334

(57) ABSTRACT

A method for manufacturing a semiconductor device, the method including forming a front face structure of a semiconductor device on a first main face of a semiconductor substrate, grinding a second main face of the semiconductor substrate and reducing the semiconductor substrate in thickness to a thickness equal to or less than 100 μm, ion implanting a dopant into the second main face of the semiconductor substrate of reduced thickness, and activating the dopant by irradiating the second main face with laser light and performing laser annealing while the semiconductor substrate of reduced thickness is heated.

### CROSS-REFERENCE TO RELATED APPLICATIONS

This application is a continuation, under 35 U.S.C. 111(a), of international application No. PCT/JP2011/051625 filed on Jan. 27, 2011, which claims priority to Japanese Patent Application No. 2010-023378, filed on Feb. 4, 2010, the disclosures of which are incorporated herein by reference.

### BACKGROUND

1. Field

The present invention relates to a method for manufacturing a semiconductor device.

2. Description of the Related Art

Power integrated circuits (IC), in which electric circuits are comprised of a large number of transistors or resistors and integrated power semiconductor devices, have been widely used for important components of computers and communication equipment.

An insulated gate bipolar transistor (IGBT) is a power semiconductor device which combines high-speed switching and voltage drive characteristics of a MOSFET (MOS gate field-effect transistor) with low ON voltage characteristic of a bipolar transistor. IGBTs find wide application in industrial fields of universal inverters, AC servers, uninterrupted power supplies (UPS), as well as switching power supplies and consumer equipment such as microwave ovens, electric rice cookers, and stroboscopes. With the development of next-generation insulated gate bipolar transistors, transistors with novel chip structures and lower ON voltage have been developed, which has resulted in a decrease in loss and increase in efficiency of application equipment.

The IGBT structure can be a punch through (PT) type, a non punch through (NPT) type, or a field stop (FS) type. Practically all of the IGBTs that are presently mass produced (with the exception of some p-channel IGBTs for audio power amplifiers) have an n-channel vertical two-layer diffusion structure. In the description below, an IGBT will be assumed to be an n-channel IGBT, unless specifically stated otherwise.

A PT-type IGBT has a structure in which an n⁺ layer (n⁺ buffer layer) is provided between a p⁺ epitaxial substrate (p⁺ collector layer) and an n⁻ layer (n⁻ active layer) and a depletion layer in the n⁻ active layer reaches the n buffer layer, this being a mainstream basic structure for IGBTs. Typically, a 70 μm thickness of the n⁻ active layer is sufficient for an IGBT with a voltage resistance of a 600 V system, but when a p⁺ epitaxial substrate portion is included, the total thickness becomes about 200 μm to 300 μm, which is rather large. Accordingly, NPT-type and FS-type IGBTs have been developed in which thickness and cost are reduced by using a Floating Zone (FZ) substrate formed by a FZ method that forms a shallow p+ collector layer instead of using a p⁺ epitaxial substrate.

FIG. 9 illustrates a cross-sectional view of the principal portion of the conventional NPT-type IGBT using a shallow p⁺ collector layer with a low dose amount. This is the cross-sectional view of a ½ cell. An NPT-type IGBT uses a low-dose shallow p⁺ collector layer 22 (low-implantation p⁺ collector layer) that also serves as a support substrate, instead of the p⁺ epitaxial substrate. Therefore, the total thickness of the substrate is substantially less than that of the PT-type IGBT. In such a structure, the injection efficiency of holes can be controlled. As a result, high-speed switching can be performed without life time control. However, the thickness of the n⁻ active layer 21 is greater than that in the PT-type IGBT and the injection efficiency of the p⁺ collector layer is lower, which results in a higher ON voltage value. However, since the FZ substrate is inexpensive compared to the p⁺ epitaxial substrate, the chip has reduced cost.

The following reference numerals are used in the figures: 1 is a FZ-N substrate, 2 is a gate oxidation film, 3 is a gate electrode, 4 is a p⁺ base layer, 5 is an n⁺ emitter layer, 6 is an interlayer insulating film, 7 is an emitter electrode, and 11 is a back face electrode (collector electrode). In the present description and the appended drawings, the reference symbols n and p assigned to layers or regions indicate that these layers or regions include a large number of electrons or holes, respectively. Further, the reference symbols + and − assigned to n or p indicate that the concentration of dopant is higher or lower than that in the layers without such assignment.

FIG. 10 illustrates a cross-sectional view of the principal portion of a conventional FS-type IGBT. The basic structure is identical to that of the PT-type IGBT. However, the PT-type IGBT uses a thick p⁺ epitaxial substrate, while the FS-type IGBT uses the FZ-N substrate 1. As a result, the total thickness of the FS-type IGBT is reduced by 100 μm to around 200 μm. In addition, the PT-type and FS-type IGBTs both have a depleted n⁻ active layer 21 with a thickness of about 70 μm to adapt to a 600 V voltage resistance. For this purpose, the n⁺ field stop layer 9 is provided below the n⁻ active layer 21.

The n⁺ field stop layer 9 acts similarly to the n⁺ buffer layer formed in the PT-type IGBT. On a side closer to the collector, a shallow p⁺ diffusion layer 10 with a low dose amount is used as a low-implantation p⁺ collector layer. As a result, life time control is not required, as it would be for a NPT-type IGBT. There are also FS-type IGBTs of a trench gate structure, in which a narrow, deep groove (trench) is formed in the chip surface (not shown in FIG. 10) and a MOS gate structure is formed on the side face thereof to further reduce the ON voltage. The total thickness of the substrate has recently been decreased further by design optimization.

In addition, matrix converters that perform direct AC-AC conversion, without intermediate DC conversion, have attracted much attention. In contrast to conventional inverters, matrix converters do not require a capacitor, and thus, the high frequency of power supply can be reduced. However, since the input is an alternating current, a resistance to reverse voltage is required for a semiconductor switch. When the conventional IGBT is used, a reverse blocking diode should be connected in series to enable reverse blocking of the device used.

FIG. 11 illustrates a cross-sectional view of the principal portion of a conventional reverse blocking IGBT. This reverse blocking IGBT can withstand a reverse voltage, while maintaining the basic performance of the conventional IGBT. The basic configuration, other than the presence of a separation layer 24 (p⁺ layer) for imparting the reverse blocking capability, is identical to that of the NPT-type IGBT. Since the reverse blocking IGBT does not require a series diode, the conduction loss can be reduced by half, which significantly increases the conversion efficiency of a matrix converter. A combination of a technique to form deep junctions with a depth greater than or equal to 100 μm (technique of forming a separation layer) and a technique to produce extremely thin wafers with a thickness less than or equal to 100 μm (thickness reduction technique) made it possible to manufacture a high-performance reverse blocking IGBT.

However, in order to realize a thin IGBT with a total thickness of about 70 μm, it is necessary to resolve production problems, such as back grinding of a back face, ion implantation from the back face, heat treatment of the back face, and warping of thin wafers.

FIGS. 12 to 18 are cross-sectional views illustrating a method for manufacturing a conventional FS-type IGBT. In FIGS. 12 to 18, the cross-sectional views of the principal portions of a semiconductor device in the manufacturing process are shown in the order of process steps. The formation of the FS-type IGBT on the substrate can generally be divided into a front face side process and a back face side process. For the front face side process, a front face structure 8 of the device shown in FIG. 15 is comprised of a gate oxidation film 2, a gate electrode 3, a p⁺ base layer 4, an n⁺ emitter layer 5, an interlayer insulating film 6, and an emitter electrode 7.

First, SiO₂ and a polysilicon are deposited on the front face side of the FZ-N substrate 1b, and the gate oxidation film 2 and the gate electrode 3 are formed by window opening processing using photolithography. As a result, an insulating gate structure (MOS gate structure) is formed on the front face side of the FZ-N substrate 1b (FIG. 12). The window opening processing as referred to herein is a processing of selectively removing the gate oxidation film 2 and the gate electrode 3 and exposing the front face of the FZ-N substrate 1b.

Then, the p⁺ base layer 4 is formed on the front face side of the FZ-N substrate 1b, and the n⁺ emitter layer 5 is formed in this p⁺ base layer 4. In this case, the p⁺ base layer 4 and the n⁺ emitter layer 5 are formed by self-alignment, using the gate electrode 3 as a mask. Then, BPSG (Boro-Phoshpo Silicate Glass) is deposited on the front face side of the FZ-N substrate 1b and window opening processing is performed to form the interlayer insulating film 6 (FIG. 13). The p⁺ base layer 4 and the n⁺ emitter layer 5 are selectively exposed by the window opening processing.

Next, an aluminum-silicon film is deposited to be in contact with the n⁺ emitter layer 5, and a front face electrode serving as the emitter electrode 7 is formed. In order to realize stable joining ability and a low-resistance wiring, the aluminum-silicon film is then heat treated at a low temperature of about 400° C. to 500° C. Subsequently, an insulating protective film (not shown in the FIGS.) is formed by using a polyimide or a similar compound to cover the front face of the FZ-N substrate 1b (FIG. 14), which completes the front face structure 8 (FIG. 15).

In the back face side process, the FZ-N substrate 1b is polished by back grinding or etching from the front face side to the desired thickness, and wafer thickness is reduced (thickness reduction) and a thin FZ-N substrate 1 is obtained (FIG. 15). Then, ion implantation 12 of phosphorus (P) and ion implantation 13 of boron (B) are performed sequentially into the back face 1a side of the FZ-N substrate 1, and the n⁺ layer 9a and the p⁺ layer 10a are formed (FIG. 16).

A low-temperature heat treatment at a temperature of 350° C. to 500° C. is then performed in an electric furnace (not shown in the FIGS.) or laser annealing is performed by irradiation with a laser light 14 from the back face 1a. As a result, the phosphorous-implanted n⁺ layer 9a and the boron-implanted p⁺ layer 10a are activated and the FS layer 9 (n⁺ field stop layer) and the p⁺ collector layer 10 are formed. The actual irradiation with laser light is performed on the back face 1a after fixing the FZ-N substrate 1 with an electrostatic chuck or the like (FIG. 17).

A back face electrode 11 comprising a combination of metal films such as an aluminum layer, a titanium layer, a nickel layer, and a gold layer is formed on the front surface of the p⁺ collector layer 10 (FIG. 18). Finally, an aluminum wire is fixedly attached by ultrasonic wire bonding to the emitter electrode 7, which is the front face electrode, after dicing to a chip-like shape (not shown in FIG. 18). A predetermined fixing member is connected by a solder layer to the back face electrode 11, which completes the fabrication of the FS-type IGBT 200.

Ion implantation when the substrate is heated and a combination of ion implantation and laser annealing techniques when the substrate is heated have been suggested as methods for activating the dopant layer (see, for example, Patent Document 1 below). The manufacturing apparatus used in the case of using (additionally using) the technique described in Patent Document 1 is provided with four structural units, namely, an ion implantation unit, a laser irradiation unit, an optical system mirror, and a substrate heating unit. When the technique described in Patent Document 1 is not used (is not additionally used), for example, the ion implantation unit, from among the four abovementioned structural units serves as a component separate from other structural units, and the manufacturing method is similar, for example, to the method for manufacturing the conventional FS-type IGBT 200 shown in FIGS. 12 to 18.

Further, a method for activating the ion implantation layer by using two laser annealing apparatuses with different wavelengths has been suggested as a separate method (see, for example, Patent Document 2).

Further, the back face concentration and activation ratio of a FS-IGBT have also been suggested (see, for example, Patent Document 3).

FIG. 19 is a configuration diagram illustrating the principal portion of the usual laser annealing apparatus. In the laser annealing apparatus shown in FIG. 19, the FZ-N substrate 1 is fixed with an electrostatic chuck 17, and the back face 1a of the FZ-N substrate 1 is irradiated via an optical system mirror 16 with the laser light 14 emitted from a laser irradiation unit 15. In the laser annealing apparatus, the back face 1a side of the FZ-N substrate 1 is laser annealed to activate the dopants that have been introduced into the back face 1a side.
Patent Document 1: Japanese Patent Application Publication No. 2005-268487
Patent Document 2: Japanese Patent Publication No. 4043865
Patent Document 3: Japanese Patent Publication No. 4088011

The above-described contents indicate that the following problems are associated with conventional manufacturing methods.

First, when the activation ratio is increased so as to obtain a predetermined diffusion profile in the FS layer 9 of a FS-type IGBT, this cannot be attained by low-temperature (350° C. to 500° C.) heat treatment in an electric furnace.

Second, when the FZ-N substrate 1 is in a room temperature state, the repair of defects in the FS layer 9 is insufficient when a laser annealing method has been used.

Third, in the usual laser annealing apparatus, no mechanism is provided for heating the substrate. Therefore, in order to perform the repair of defects indicated in the preceeding paragraph, it is necessary to separately perform a heat treatment at a low temperature (350° C. to 500° C.). In this case, the heat treatment is performed at a low temperature because the aluminum electrode (emitter electrode 7) has been formed on the front face side.

Fourth, in the usual laser annealing apparatus, the FZ-N substrate 1 is fixed to an electrostatic chuck 17 (see FIG. 19), and a heating mechanism is difficult to attach to the electrostatic chuck 17. For this reason, laser annealing cannot be performed in a state in which the FZ-N substrate 1 is heated.

Fifth, a problem associated with the method described in Patent Document 1 is that when ion implantation and laser annealing are performed simultaneously while heating the substrate, regions appear in the substrate, into which ions have been implanted but have not yet been irradiated with laser light, unless control is performed to ensure the duration of ion implantation is substantially similar to the duration of laser irradiation.

In other words, the duration of ion implantation, the duration of laser irradiation, and the chip temperature state in these processes are interrelated. Thus, the diffusion profile differs from chip to chip, and the quality ratio of devices decreases.

The spread in diffusion profile among the chips will be explained below. FIG. 20 is an explanatory drawing illustrating how the diffusion profile becomes unstable. The FZ-N substrate 1 that has been subjected to ion implantation simultaneously with laser light irradiation on the surface subjected to ion implantation is shown at the upper side of the paper sheet in FIG. 20. The irradiation is continuously performed by reciprocatingly moving the laser in a direction 101 parallel to the surface of the FZ-N substrate 1 and scanning the entire substrate. A characteristic illustrating the activation state of the FZ-N substrate 1 irradiated with the laser light is shown at the lower side of the paper sheet in FIG. 20. The depth from the back face 1a of the FZ-N substrate 1 is plotted against the abscissa in the characteristic diagram in FIG. 20. The p⁺ collector layer 10 and the FS layer 9 are formed in the order of description to a depth of 1 μm from the back face 1a in the back face 1a of the FZ-N substrate 1. The reference symbols p and n in the characteristic diagram represent the p⁺ collector layer 10 and the FS layer 9 respectively. In the ion implantation performed to form the FS layer 9, the dopant was boron (B), the acceleration energy was 50 keV, and the dose amount was 1.0×10¹⁵ cm⁻². In the ion implantation performed to form the p⁺ collector layer 10, the dopant was phosphorus (P), the acceleration energy was 240 keV, and the dose amount was 1.0×10¹³ cm⁻². The temperature of the FZ-N substrate 1 during ion implantation was maintained at 400° C.

As shown in the characteristic diagram in FIG. 20, in a region (laser annealed chip) 102 subjected to irradiation with laser light, the activation is performed along a curve 111 shown by a solid line. In other words, the curve 111 represents the activation state in the case where ion implantation and laser irradiation are performed at the same time. The laser annealing is performed using a YAG 2ω laser with an irradiation energy density of 2.8 J/cm². Meanwhile, in a region (chip that has not been laser annealed) 103 that has not been irradiated with laser light, the activation of the p⁺ collector layer 10 and the FS layer 9 is insufficient as shown by a curve 112 represented by a dot line. Such a result is obtained in the case where the time required for ion implantation into the entire substrate surface is shorter than the time required for laser irradiation under the conditions of simultaneous performance of ion implantation and laser irradiation. Further, when ion implantation is performed at room temperature (the planar shape of the chip is not shown in the figure), the p⁺ collector layer 10 and the FS layer 9 are not activated, as shown by a curve 113 represented by a dot-dash line.

Further, when the technique described in Patent Document 1 is used (also used), the manufacturing apparatus is constituted by an ion implantation unit, a laser irradiation unit, and a substrate heating unit. As a result, the size of the manufacturing apparatus is very large. When the technique described in Patent Document 1 is not used (not also used), the laser irradiation energy should be increased in order to increase the activation ratio of the ion-implanted dopants and the substrate surface can be damaged. Further, when dopants with a low penetration depth and dopants with a high penetration depth in ion implantation are activated at the same time, the dopants of both types are difficult to activate with good efficiency.

Finally, the afore-mentioned Patent Document 2 and Patent Document 3 do not describe the feature of performing laser annealing in a state in which the substrate is heated after ion implantation, which is a specific feature of the present invention.

### SUMMARY

It is an object of embodiments of the present invention to resolve the above-described problems inherent to the related art and to increase the activation ratio of dopants that have been ion implanted into the back face, without adversely affecting the front face structure of the device. Another object of embodiments of the present invention is to sufficiently repair the crystal defects caused by ion implantation and obtain the desired diffusion profile.

According to an aspect of the present invention, there is provided a method for manufacturing a semiconductor device that has the following features. First, a step is performed of forming a front face structure, such as an emitter layer and a gate electrode of a semiconductor device, for example, a FS-type IGBT, on a first main face of a semiconductor substrate, for example, a FZ-N substrate. Then, a step is performed of grinding a second main face of the semiconductor substrate and reducing the semiconductor substrate in thickness to a thickness equal to or less than 100 μm (also referred to as film thickness reduction). Then, a step is performed of ion implanting a dopant, for example, phosphorus or boron, into the rear face which is the second main face of the semiconductor substrate of reduced thickness. Then, a step is performed of activating the dopant by irradiating the second main face with laser light and performing laser annealing in a state in which the semiconductor substrate of reduced thickness is heated. In the laser annealing step, the heating temperature of the semiconductor substrate is 100° C. to 500° C. The wavelength of the laser light used in the laser annealing is 200 nm to 900 nm. The irradiation energy density of the laser light is 1.2 J/cm² to 4 J/cm². Further, the laser light is constituted by YAG 2ω laser light and semiconductor laser light, and irradiation with the YAG 2ω laser light and the semiconductor laser light is performed simultaneously.

According to another aspect of the present invention, there is provided a method for manufacturing a semiconductor device that has the following features. First, a step is performed of forming a front face structure, such as an emitter layer and a gate electrode of a semiconductor device, for example, a FS-type IGBT, on a first main face of a semiconductor substrate, for example, a FZ-N substrate. Then, a step is performed of grinding a second main face of the semiconductor substrate and reducing the semiconductor substrate in thickness to a thickness equal to or less than 100 μm (also referred to as film thickness reduction). Then, a step is performed of ion implanting a dopant, for example, phosphorus or boron, into the rear face which is the second main face of the semiconductor substrate of reduced thickness. Then, a step is performed of activating the dopant by irradiating the second main face with laser light and performing laser annealing in a state in which the semiconductor substrate of reduced thickness is heated. In the laser annealing step, the heating temperature of the semiconductor substrate is 100° C. to 500° C. The wavelength of the laser light used in the laser annealing is 200 nm to 900 nm. The irradiation energy density of the laser light is 1.2 J/cm² to 4 J/cm². Further, the laser light is radiated from two YAG 2ω lasers and the two laser lights are radiated as 100 ns pulses with a spacing of 500 ns.

By performing the laser annealing under heating, it is possible to increase the activation ratio. Further, with the heating temperature within the above-mentioned range, the dopants that have been ion implanted in the back face of the substrate can be activated without adversely affecting the front face structure of the semiconductor device that has been formed on the front face of the substrate. With the wavelength within the above-mentioned range, dopants with a diffusion depth as large as about 1 μm can be efficiently activated. Further, with the irradiation energy density within the above-mentioned range, the activation ratio of the dopants that have been ion implanted in the back face can be increased. Where the irradiation energy density is outside the above-mentioned range, a high activation ratio is difficult to obtain or an adverse effect is produced on the front face structure. With the above-mentioned combination of laser lights, it is possible to obtain the wavelength of laser light within a wide range and to activate a diffusion layer with a small diffusion depth (p⁺ collector layer and the like) and a deep diffusion layer (FS layer) with good efficiency and high activation ratio.

According to another aspect of the present invention, there is provided an apparatus for manufacturing a semiconductor device in accordance with the present invention, the apparatus comprising a support unit that supports a semiconductor substrate, an irradiation unit that irradiates the semiconductor substrate with laser light, and a heating unit that heats the semiconductor substrate.

With the apparatus for manufacturing a semiconductor device of the above-mentioned configuration, a laser annealing apparatus having a heating mechanism is obtained.

According to another aspect of the present invention, the support unit and the heating unit are integrated to configure a substrate heating unit (e.g., a hot plate) that has a guide that fixes the semiconductor device and heats the semiconductor substrate.

When the substrate is heated during activation of the ion implantation layer, a state is assumed in which the ion implantation layer is easily activated under the effect of heating. In this case, when laser irradiation is performed, the effect of heat on activation is increased and activation is facilitated as opposed to the case of laser annealing performed at the room temperature. An especially significant effect of heating the substrate is produced on layers that are deep from the laser irradiation face because the heat of laser radiation is unlikely to penetrate thereto. Such an approach is effective for activating the FS layer. Further, crystal defects in the ion implantation layer can be sufficiently repaired. In addition, since the temperature of the front face structure is maintained less than or equal to 500° C. during laser annealing, no adverse effects (oxidation, melting, etc.) are produced on the emitter electrode. As a result, it is possible to provide a method for manufacturing a semiconductor device with good characteristics and a high activation ratio.

An effect demonstrated by the semiconductor apparatus in accordance with embodiments of the present invention is that the activation ratio of the dopant that has been ion implanted in the back face can be increased without adversely affecting the front face structure of the device. Additionally, since the crystal defects caused by ion implantation can be sufficiently repaired, another effect is that the desired diffusion profile can be obtained with a small spread.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a cross-sectional view illustrating the method for manufacturing a semiconductor device according to Embodiment 1.

FIG. 2 is a cross-sectional view illustrating the method for manufacturing a semiconductor device according to Embodiment 1.

FIG. 3 is a cross-sectional view illustrating the method for manufacturing a semiconductor device according to Embodiment 1.

FIG. 4 is a cross-sectional view illustrating the method for manufacturing a semiconductor device according to Embodiment 1.

FIG. 5 is a characteristic diagram illustrating the diffusion profile of the FS-type IGBT 100.

FIG. 6 is a characteristic diagram illustrating the relationship between the depth of the FS layer and the substrate temperature using irradiation energy density as a parameter.

FIG. 7 is a characteristic diagram illustrating the relationship between the depth of the FS layer and the substrate temperature using laser configuration as a parameter.

FIG. 8 is a configuration diagram illustrating the principal portion of the apparatus for manufacturing a semiconductor device according to Embodiment 2.

FIG. 9 is a cross-sectional view illustrating the principal portion of the conventional NPT-type IGBT using a shallow p⁺ collector layer with a low dose amount.

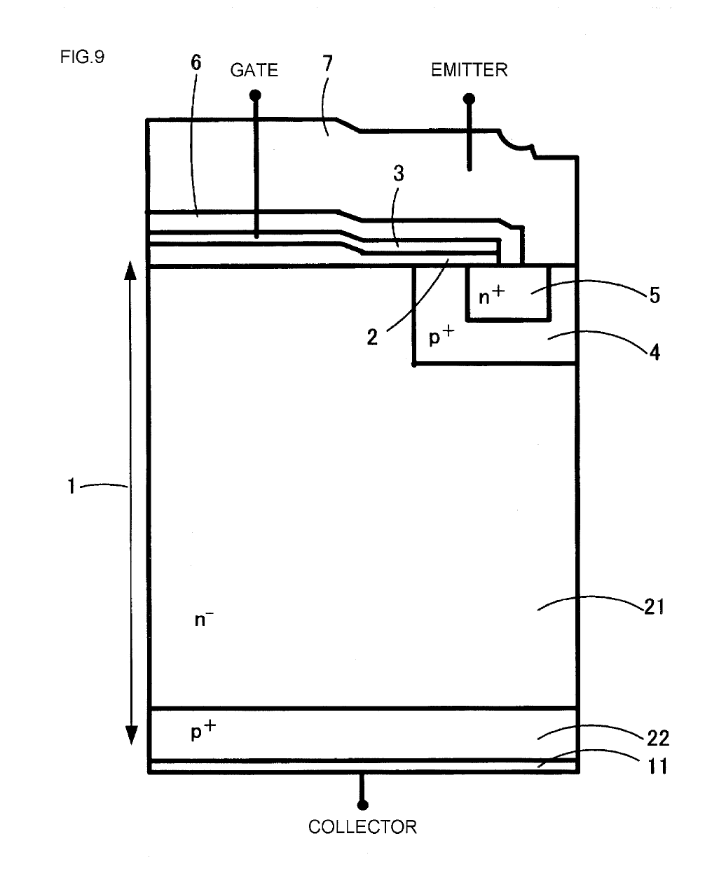

FIG. 10 is a cross-sectional view illustrating the principal portion of the conventional FS-type IGBT.

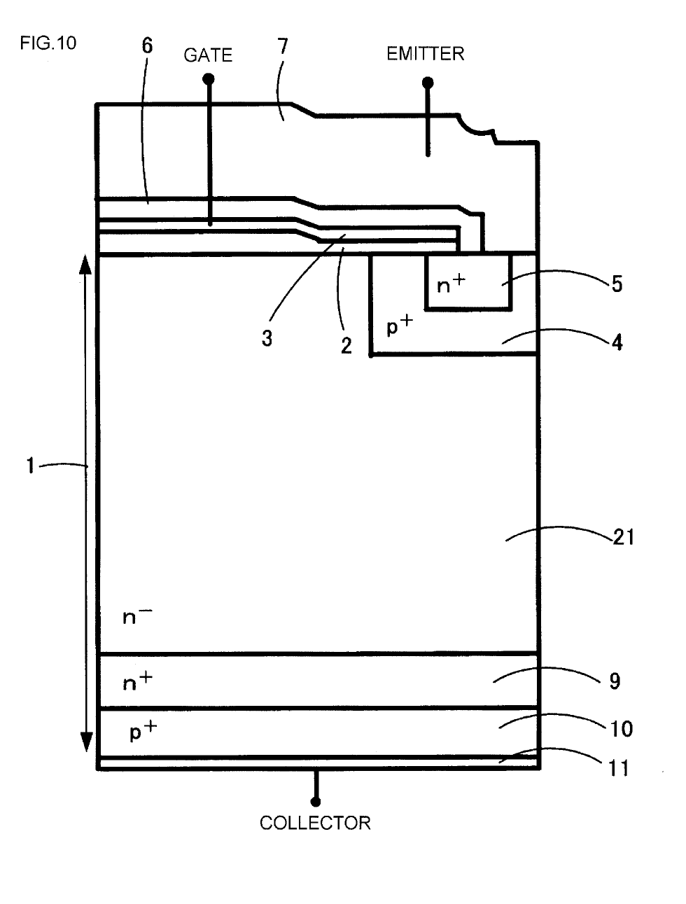

FIG. 11 is a cross-sectional view illustrating the principal portion of a reverse blocking IGBT.

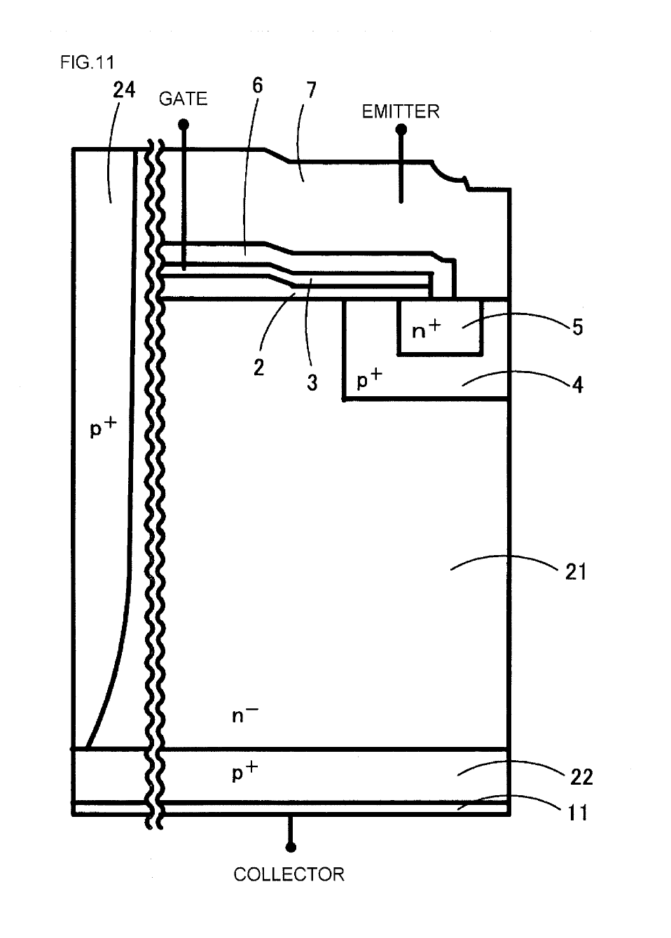

FIG. 12 is a cross-sectional view illustrating the conventional method for manufacturing a FS-type IGBT.

FIG. 13 is a cross-sectional view illustrating the conventional method for manufacturing a FS-type IGBT.

FIG. 14 is a cross-sectional view illustrating the conventional method for manufacturing a FS-type IGBT.

FIG. 15 is a cross-sectional view illustrating the conventional method for manufacturing a FS-type IGBT.

FIG. 16 is a cross-sectional view illustrating the conventional method for manufacturing a FS-type IGBT.

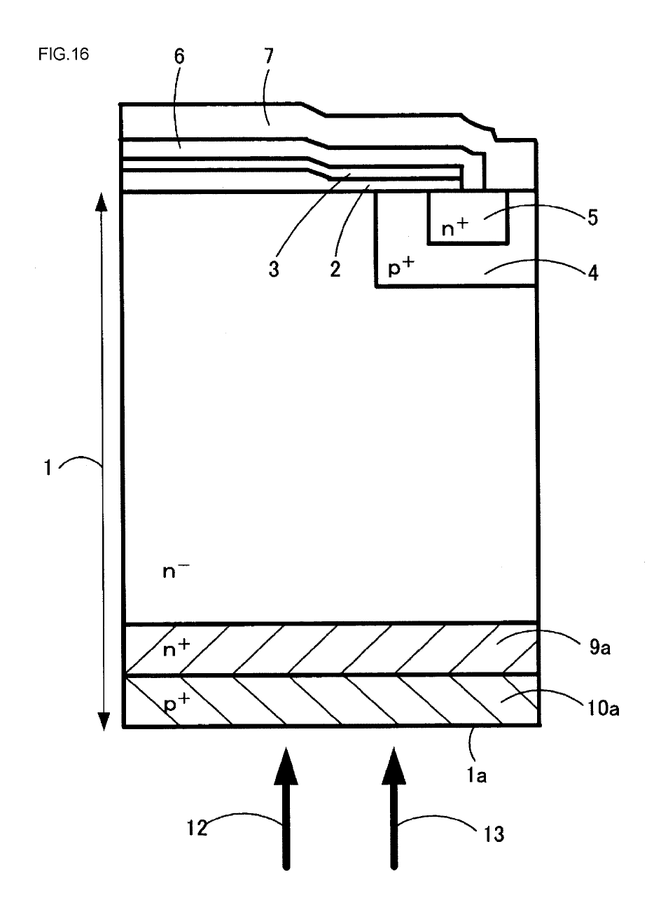

FIG. 17 is a cross-sectional view illustrating the conventional method for manufacturing a FS-type IGBT.

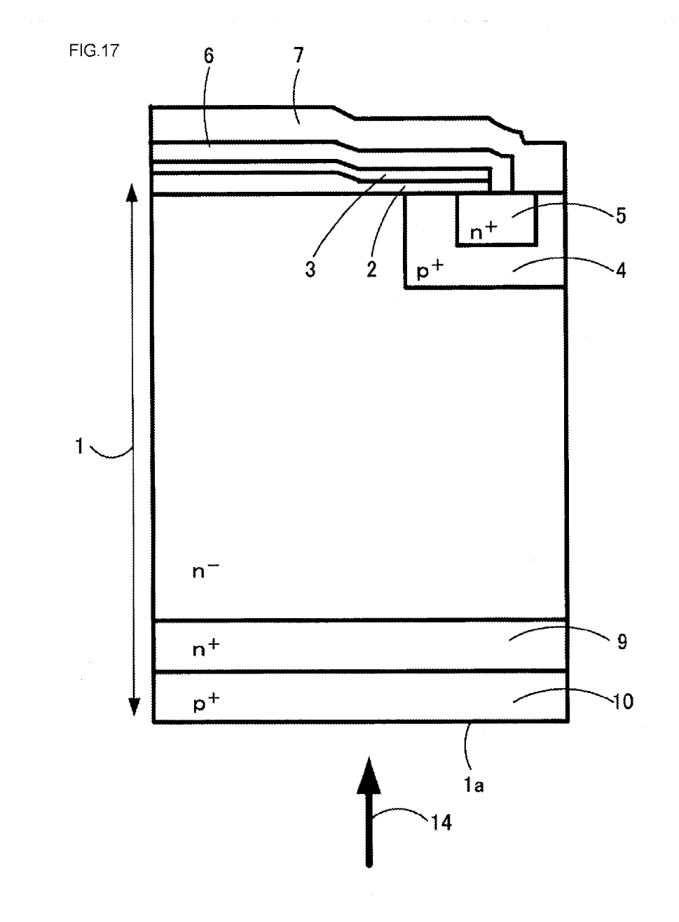

FIG. 18 is a cross-sectional view illustrating the conventional method for manufacturing a FS-type IGBT.

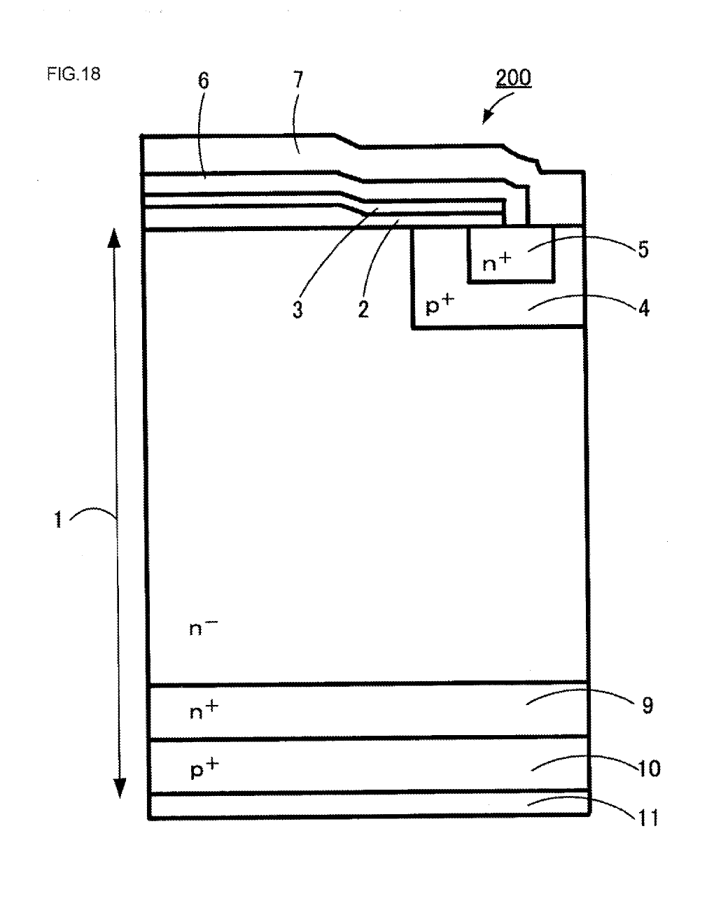

FIG. 19 is a configuration diagram illustrating the principal portion of the conventional laser annealing apparatus.

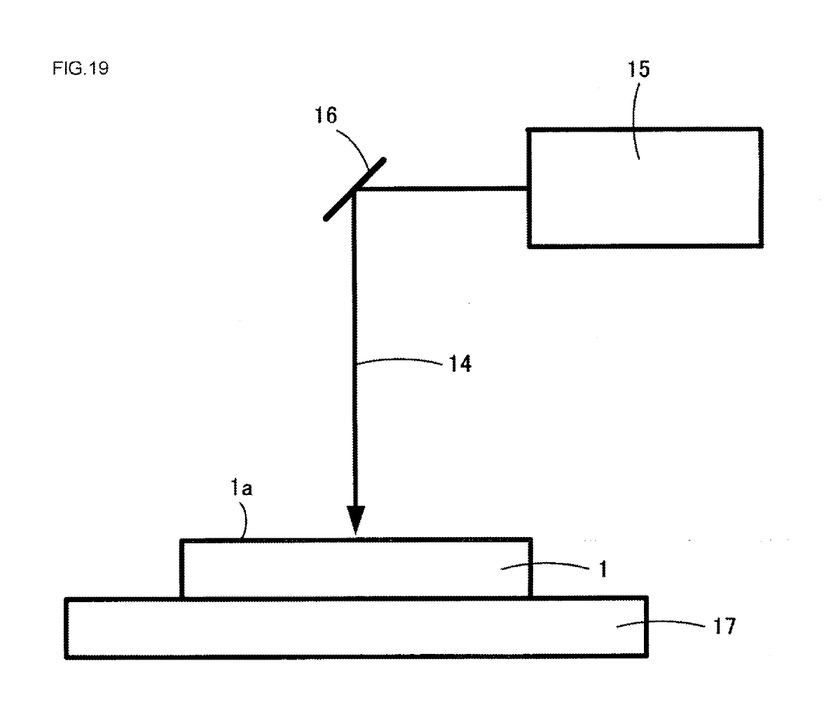

FIG. 20 is an explanatory drawing illustrating how a diffusion profile becomes unstable.

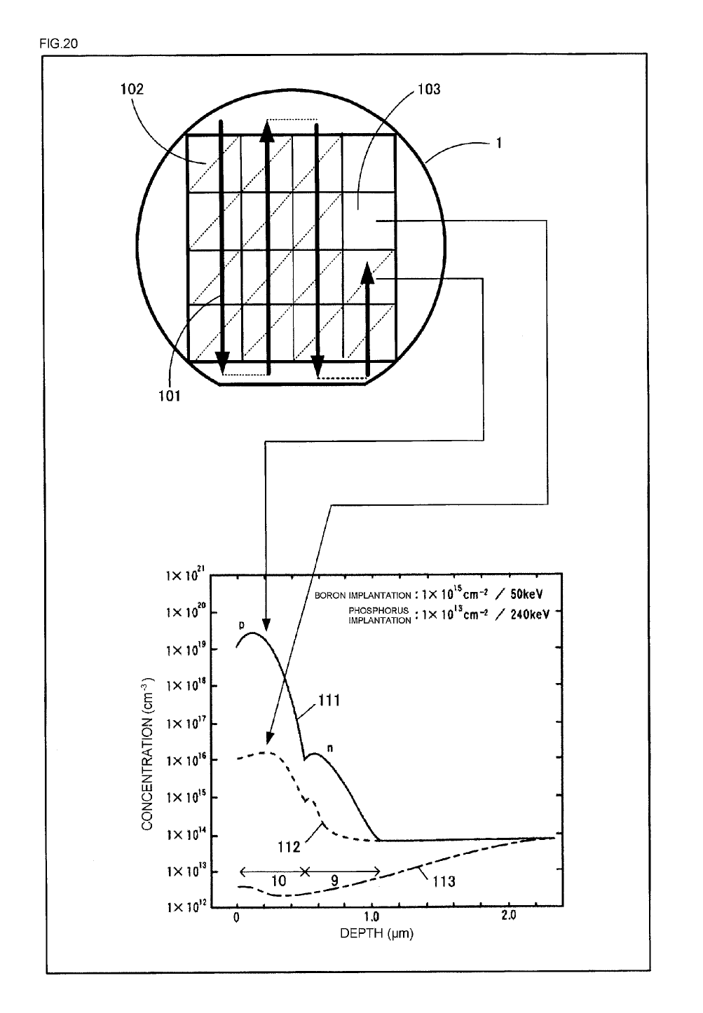

### DESCRIPTION OF EMBODIMENTS

Reference will now be made in detail to the embodiments, examples of which are illustrated in the accompanying drawings, wherein like reference numerals refer to the like elements throughout. The embodiments are described below to explain the present invention by referring to the figures. In the following description, the reference symbols n and p assigned to layers or regions indicate that these layers or regions include a large number of electrons or holes, respectively. Further, the reference symbols + and − assigned to n or p indicate that the concentration of dopant is respectively higher or lower than that in the layers without such assignment.

### Embodiment 1

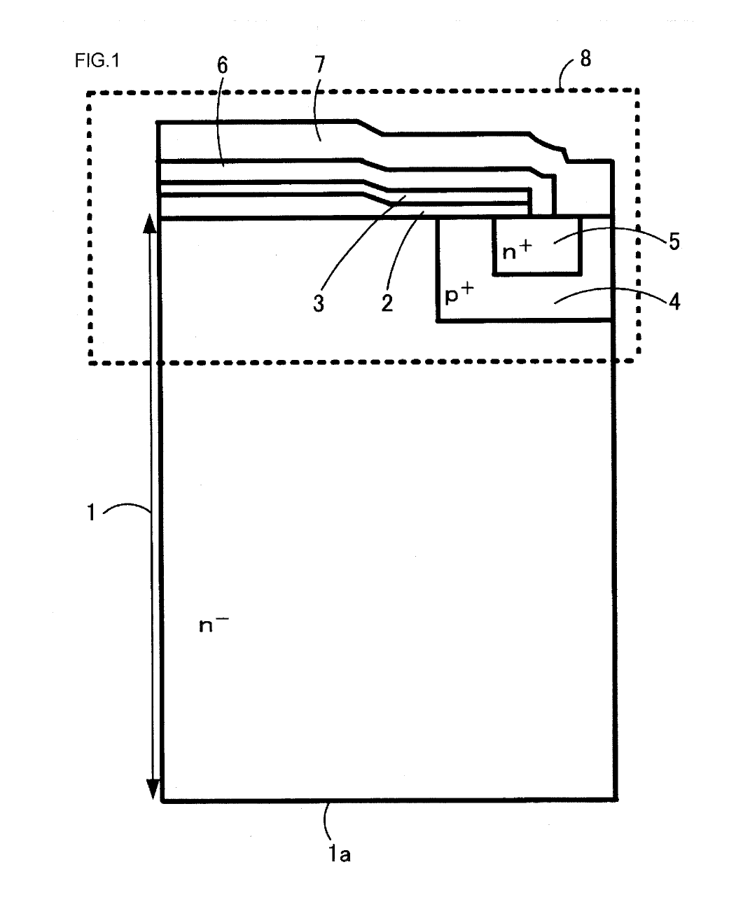

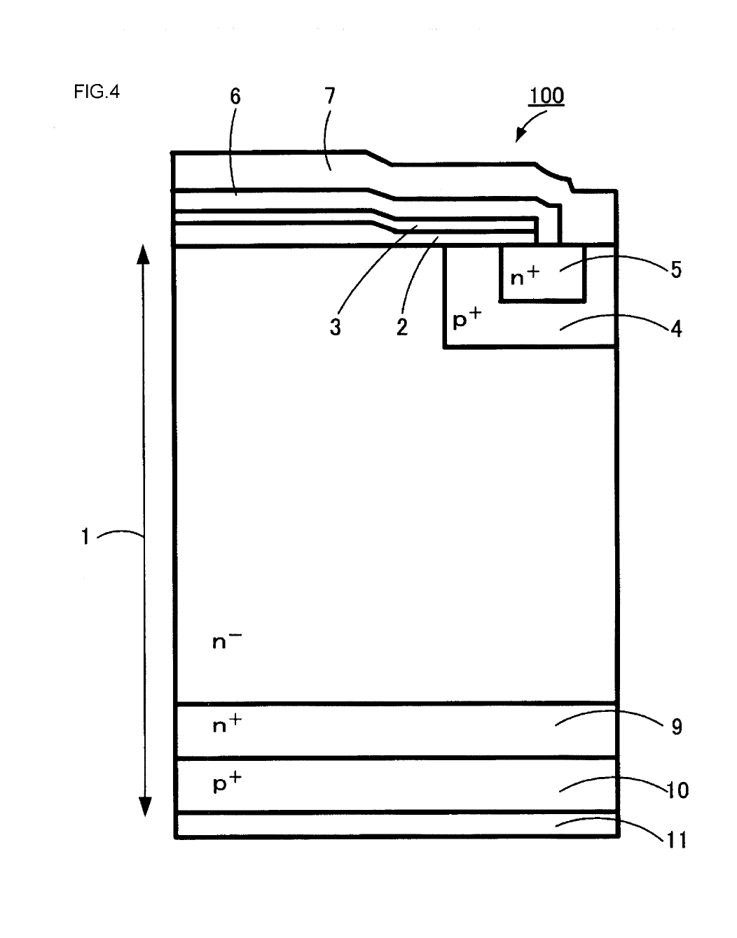

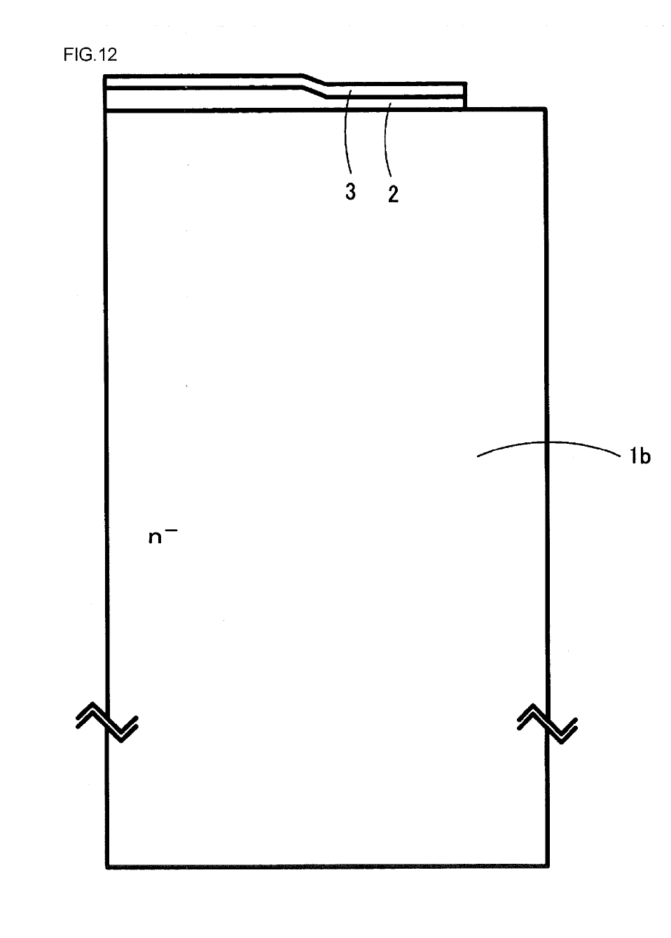

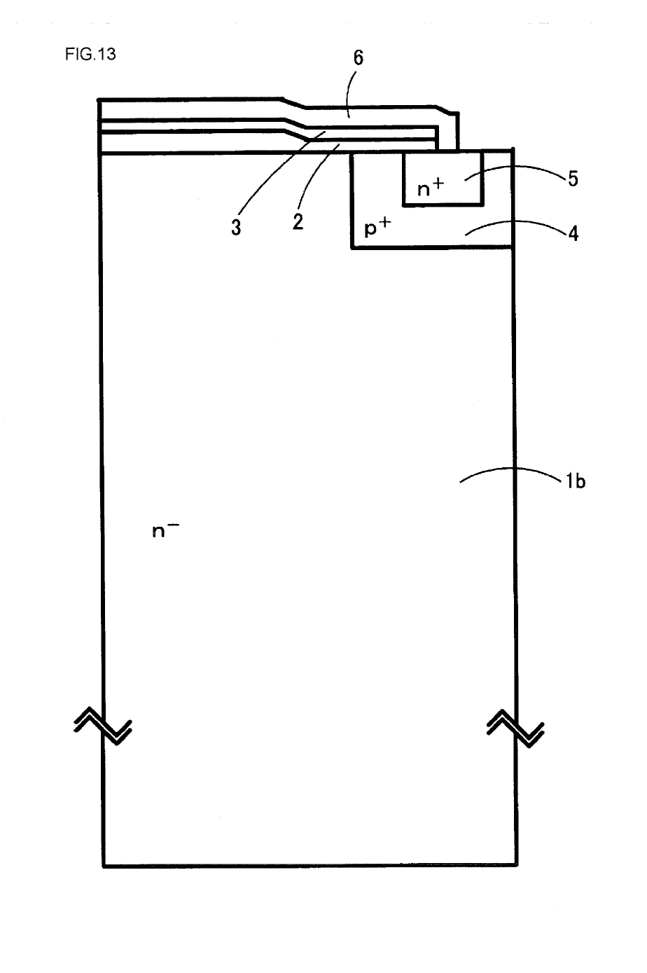

FIGS. 1 to 4 are cross-sectional views illustrating the method for manufacturing a semiconductor device according to Embodiment 1. In FIGS. 1 to 4, the cross-sectional views of the principal portion of the semiconductor device in the manufacturing process are shown in sequence. A FS-type IGBT 100 (see FIG. 4) is considered as an example of the semiconductor device. In the manufacturing process, the process performed on the front face side is identical to the conventional process (see FIGS. 12 to 14). Therefore, only the back face side process is explained herein. Portions identical to those of the conventional configuration are assigned with same reference numerals.

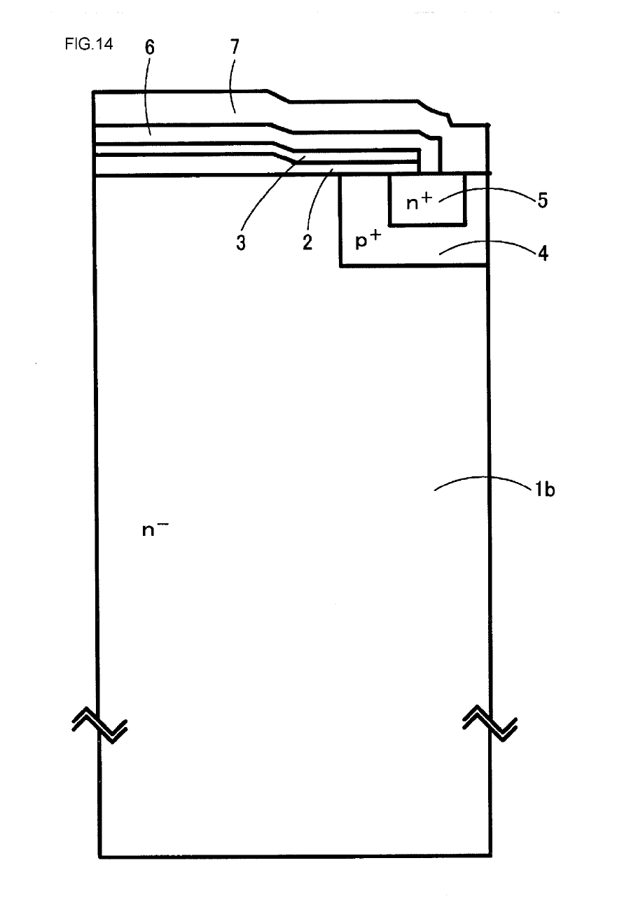

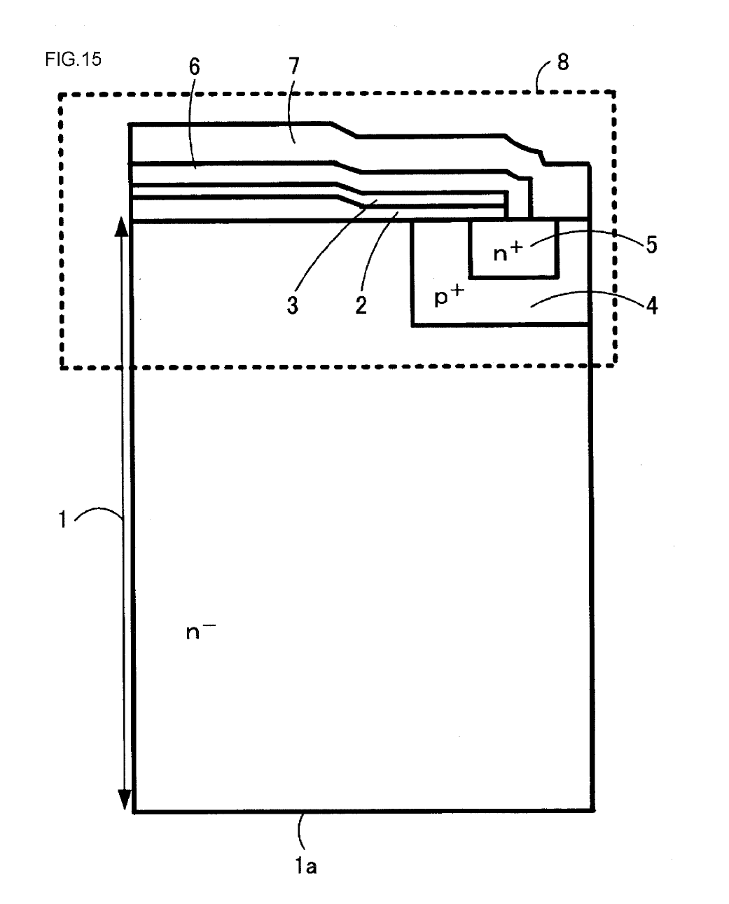

A front face structure 8 is formed on the front face of a FZ-N substrate 1b. Then, as shown in FIG. 14, the FZ-N substrate 1b is polished by back grinding or etching to the desired thickness from the back face side of the FZ-N substrate 1b and a thin wafer is obtained. As a result, a thin-film FZ-N substrate 1 is obtained. This substrate is similar to the FZ-N substrate 1 shown in FIG. 15.

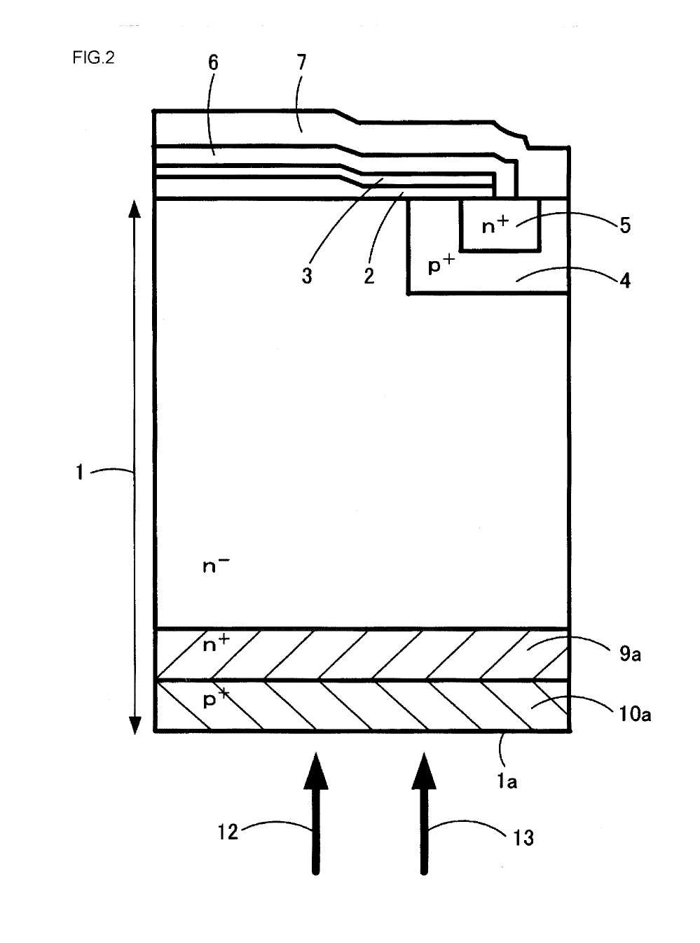

Then, ion implantation 12 of phosphorus (P) and ion implantation 13 of boron (B) are performed on the back face 1a of the FZ-N substrate 1, forming a n⁺ layer 9a, and a p⁺ layer 10a on the back face 1a of the FZ-N substrate 1. In other words, the p⁺ layer 10a is formed on the front face side of the n⁺ layer 9a. In order to ensure ohmic contact with the back face electrode (not shown in the figure), BF₂ may be implanted in a p⁺ collector layer 10 to form a p⁺⁺ layer (FIG. 2).

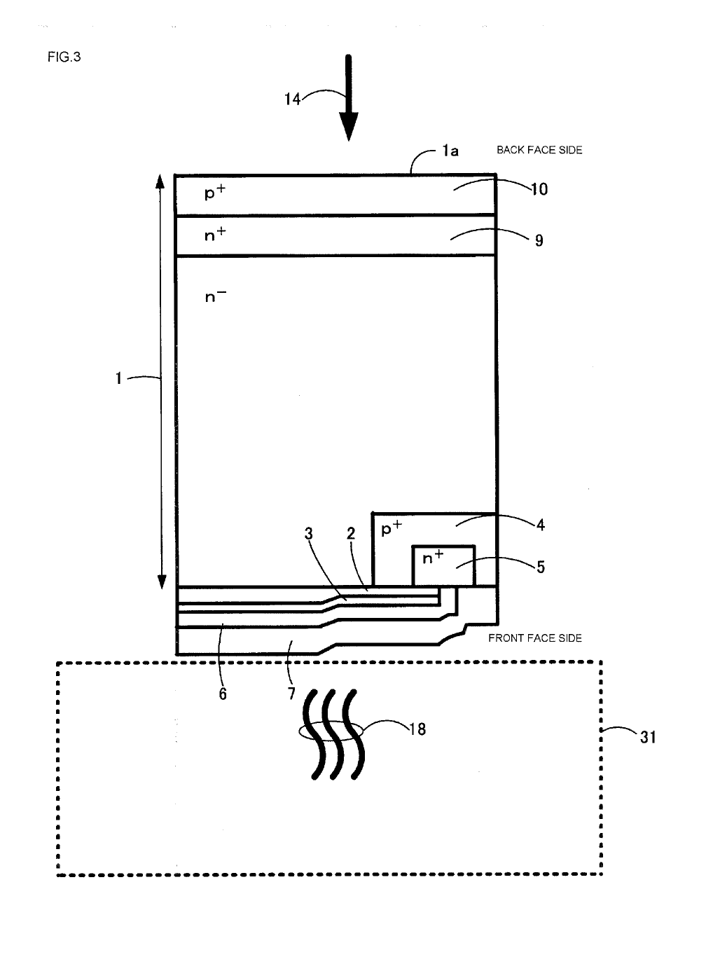

Then, the FZ-N substrate 1 is placed on a substrate heating unit 31, such as a hot plate, so that the back face 1a faces up and the front face side of the FZ-N substrate 1 is in contact with the substrate heating unit. Laser annealing by irradiation with a laser light 14 is performed from the back face 1a of the FZ-N substrate 1 such that the temperature of the FZ-N substrate 1 is maintained (for about 5 min) at a constant level between 100° C. and 500° C. by a heat 18 of the substrate heating unit 31. The n⁺ layer 9a and the p⁺ layer 10a (see FIG. 2) are activated and a FS layer 9 (n⁺ field stop layer) and a p⁺ collector layer 10 are formed. The preferred conditions of the laser annealing are as follows: the wavelength of the laser light 14 is within a range from 200 nm to 900 nm and the irradiation energy density of the laser light 14 is within a range of 1.2 J/cm² to 4 J/cm². Further, the heat treatment process is performed such that the diffusion profile of a p⁺ base layer 4 or an n⁺ emitter layer 5 does not change, and emitter electrode 7 is not oxidized and melted. In other words, the laser annealing is performed such as to produce no adverse effect on the front face structure (FIG. 3).

A back face electrode (collector electrode) 11 is then formed by laminating a metal film, such as an aluminum layer, a titanium layer, a nickel layer, and a gold layer, onto the surface of the p⁺ collector layer 10 (FIG. 4). Finally, although not shown in figures, an aluminum wire is fixed by ultrasonic wire bonding to the emitter electrode 7, which is a front face electrode. This follows dicing performed to obtain a chip-like shape and connecting a predetermined fixing member (for example, a Cu base to be fixed to the case bottom) by a solder layer to the back face electrode 11. As a result, the FS-type IGBT 100 shown in FIG. 4 is obtained.

### EXAMPLE

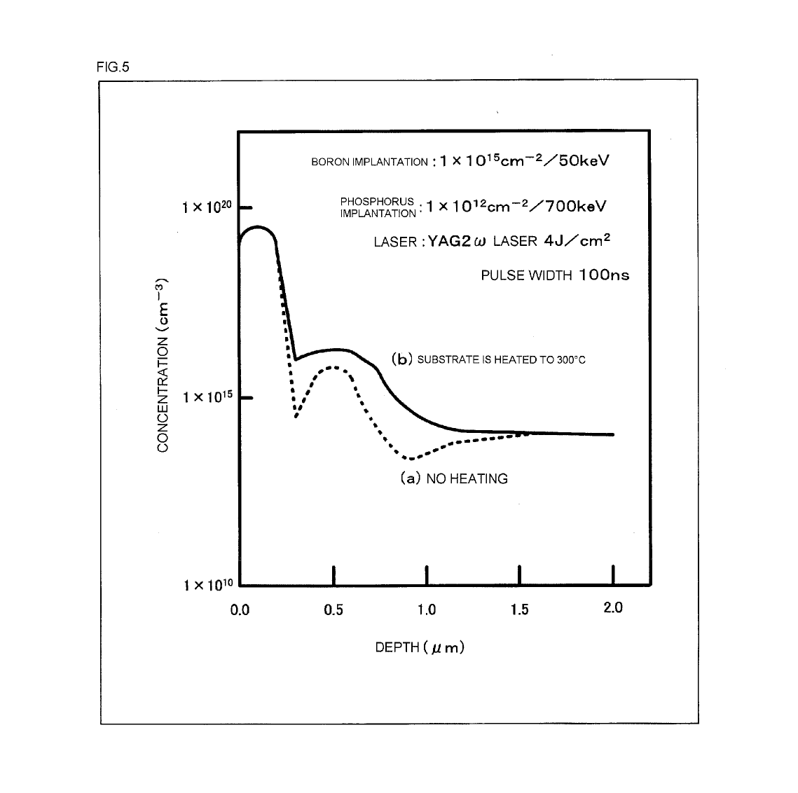

The preferred conditions of ion implantation and laser annealing will be explained below. FIG. 5 is a characteristic diagram illustrating the diffusion profile of the FS-type IGBT 100. The diffusion profile is a concentration profile measured by a Spreading Resistance (SR) method. In accordance with Embodiment 1, two types of FS-type IGBT 100 were fabricated that had different substrate temperatures during the fabrication process. The substrate temperatures were (a) room temperature (no heating; dot line in FIG. 5) and (b) 300° C. (the substrate was heated; solid line in FIG. 5). After the substrate temperature has reached the predetermined temperature, the substrate was held for 5 min and then laser annealing was performed by irradiating the back face of the substrate with laser light. A YAG 2ω laser was used as the laser, the irradiation energy density of the laser light was 4 J/cm², and the pulse width was 100 ns.

The ion implantation conditions were as follows: ion implantation dose of the boron layer, which becomes the p⁺ collector layer 10, was 1×10¹⁵ cm⁻², the acceleration voltage was 50 keV, the ion implantation dose of the phosphorus layer, which becomes the FS layer 9, was 1×10¹² cm⁻², and the accelerating voltage was 700 keV. The inclination angle during ion implantation in all cases was 7°.

The results shown in FIG. 5 indicate that the activation of the FS layer 9 is greater in the case of (b) 300° (the substrate is heated) than in the case of (a) room temperature (no heating). Further, since the ion implantation and laser annealing are performed as separate processes, as mentioned hereinabove, the laser annealing can be performed in a state in which the hot plate 31 that has been maintained in advance at a predetermined temperature and placed on the FZ-N substrate 1 so that the temperature distribution in the substrate has become uniform and constant. As a result, the IGBTs formed on the FZ-N substrate 1 have a uniform temperature; the uniform characteristics that do not depend on the formation position on the FZ-N substrate 1 are obtained for all of the IGBTs.

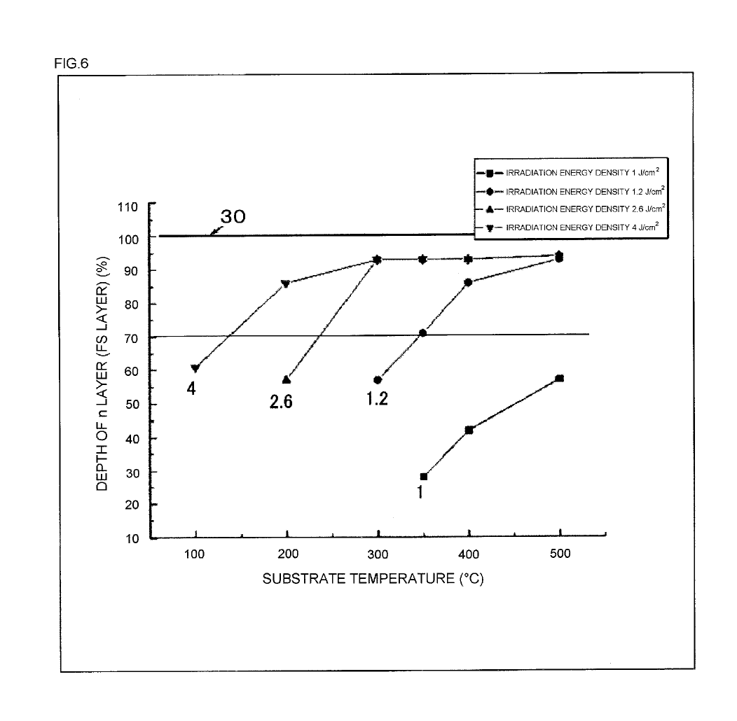

FIG. 6 is a characteristic diagram illustrating the relationship between the depth of the FS layer and the substrate temperature with irradiation energy density taken as a parameter. A plurality of FS-type IGBTs 100 was fabricated by changing the substrate temperature and irradiation energy density according to Embodiment 1. In this case, the diffusion depth (straight line 30 in FIG. 6) of the FS layer 9, obtained when the ion-implanted FZ-N substrate 1 was annealed in an electric furnace for 30 min at a temperature of 900° C., is taken to represent 100%. The ion implantation conditions were as follows: the ion implantation dose of the p⁺ layer 10a (boron layer), which becomes the p⁺ collector layer 10, was 1×10¹⁵ cm⁻², the acceleration voltage was 50 keV, the ion implantation dose of the n⁺ layer 9a (phosphorus layer), which becomes the FS layer 9, was 1×10¹² cm⁻², and the accelerating voltage was 700 keV. The inclination angle during ion implantation in all cases was 7°.

The laser annealing was performed from the back face 1a of the FZ-N substrate 1 at four different irradiation energy densities: 1 J/cm², 1.2 J/cm², 2.6 J/cm², and 4 J/cm², and five different substrate temperatures: 100° C., 200° C., 300° C., 400° C., and 500° C. It has been experimentally confirmed that the diffusion depth in laser annealing should be set to 70% of the depth obtained during annealing in an electric furnace with conditions described above in order to obtain a functional FS layer 9.

The results shown in FIG. 6 indicate that an irradiation energy density of 1 J/cm² is insufficient to obtain the depth of the FS layer 9 greater than or equal to 70%,necessary to sufficiently activate the FS layer 9. The irradiation energy density should be greater than or equal to 1.2 J/cm² to accomplish this. Meanwhile, if the irradiation energy density exceeds 4 J/cm² (this is not shown in the figure), the depth of the FS layer 9 reaches 70% even at a low substrate temperature. However, if the irradiation energy density is too high, the surface irradiated by the laser light 14 can soften and melt. Therefore, it is preferred that the irradiation energy density be within a range of 1.2 J/cm² to 4 J/cm².

When the irradiation energy density is within a range from 1.2 J/cm² to 4 J/cm², the substrate temperature may be greater than or equal to 200° C. However, if the substrate temperature becomes greater than 500° C., the aluminum electrode, which is a front face electrode (emitter electrode 7), can be oxidize and soften. Therefore, it is preferred that the substrate temperature be within a range from 200° C. to 500° C.

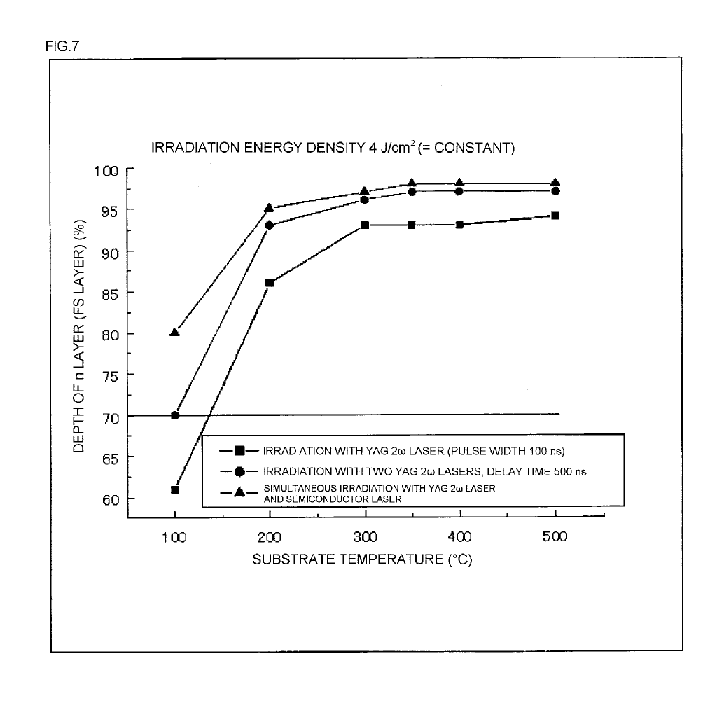

FIG. 7 is a characteristic diagram illustrating the relationship between the depth of the FS layer and the substrate temperature using a combination of lasers as a parameter. A plurality of FS-type IGBTs were fabricated according to Embodiment 1 by changing the substrate temperature and laser types. In this case, the laser annealing is performed at a constant irradiation energy density, such as 4 J/cm². The conditions of ion implantation are the same as in the case illustrated by FIG. 6. The five following substrate temperatures were used: 100° C., 200° C., 300° C., 400° C., and 500° C. The laser parameters were of the following three configurations: a single YAG 2ω laser (pulse width 100 ns) (polygonal line with ▪ symbols), two YAG 2ω lasers (pulse width 100 ns) with a delay time of 500 ns (polygonal line with symbols), and a combination of a YAG 2ω laser (pulse width 100 ns) and a semiconductor laser (wavelength 794 nm) (polygonal line with ▴ symbols).

The results shown in FIG. 7 indicate that the absorption of the laser light 14 by silicon (Si) is the highest and the penetration length of the laser light 14 is large. Furthermore, the FS layer can be formed with good stability and reproducibility, to the largest depth in the case of the combination of a YAG 2ω laser (pulse width 100 ns) and a semiconductor laser (wavelength 794 nm) (polygonal line with ▴ symbols). The semiconductor laser (DC radiation) used herein continuously emits radiation, while scanning the entire substrate within the irradiation period of the YAG 2ω laser (pulse radiation). As follows from FIG. 7, with the combination of the YAG 2ω laser and the semiconductor laser, the depth of the FS layer 9 is 80% at a substrate temperature of 100° C.

In the case of two YAG 2ω lasers (polygonal line with symbols), the depth of the FS layer 9 is 70% at a substrate temperature of 100° C. It is clear that a high activation ratio can be obtained by increasing the number of lasers (in the present embodiment, two lasers with a total energy density of 4 J/cm²) in a state with a heated substrate and conducting irradiation with a delay time within a range of 0 ns to 1000 ns (in the present embodiment, 500 ns).

Meanwhile, it is clear that in the case of a single YAG 2ω laser (pulse width 100 ns) (polygonal line with ▪ symbols), the activation ratio of the FS layer 9 is lower than that in the case of the combination of the YAG 2ω laser (pulse width 100 ns) and the semiconductor laser (wavelength 794 nm), as well as in the case of two YAG 2ω lasers.

A transmission electron microscope (TEM) image (not shown in the FIGS.) confirms that the crystal defects in the ion implantation region of the FS layer 9 are repaired as the depth of the FS layer 9 approaches the diffusion depth (the depth of 100%) obtained by annealing in the electric furnace. Supposedly, repair of crystal defects is due to the replacement of the dopant atoms introduced as interstitial defects with the Si atoms that constitute the lattice. Further, when the crystal defect repair process was examined with the TEM image and the activation of the dopant was examined from the standpoint of the degree of depth of the FS layer 9 (bias from the depth of 100%), it was found that the two processes proceed equivalently. Further, the results of TEM image examination demonstrated that the heating of the substrate is also effective for crystal defect repair.

Two lasers, namely, the semiconductor laser and the YAG 2ω (wavelength 532 nm) laser, which is a solid-state laser, are used in the present example. The solid state laser may be YLF 2ω (wavelength 527 nm), YVO4 (2ω) (wavelength 532 nm), YAG 3ω, YLF 3ω, and YVO4 (3ω). Further, an excimer laser such as XeCL (wavelength 308 nm), KrF (wavelength 248 nm), and XeF (wavelength 351 nm) may be used instead of the aforementioned solid state lasers.

Further, the wavelength of the laser light 14 used in laser annealing may be within a range of 200 nm to 900 nm. The selection of such a range can be explained as follows. Where the wavelength of the laser light 14 is less than 200 nm, the penetration depth of the laser light 14 is small, the annealing range becomes the uppermost surface layer, and such a wavelength is insufficient for annealing the FS layer 9 with a large diffusion depth. Further, where the wavelength of the laser light 14 exceeds 900 nm, the absorption range of the laser light 14 becomes deeper than the FS layer 9 and the activation ratio of the p⁺ collector layer 10 and FS layer 9 greatly decreases.

The effectiveness of substrate heating will be explained below. Where the FZ-N substrate 1 is heated during activation of the ion implantation layer, a state is assumed in which the ion implantation layer is easily activated. Where laser irradiation is performed in this case, the effect of heat on activation is increased and activation is facilitated with respect to that in the case of laser annealing performed from the room temperature. An especially significant effect of heating the substrate is produced on layers that are deep from the laser irradiation face because the heat of laser radiation is unlikely to penetrate thereto. Therefore, the process of heating the substrate is effective for activating the FS layer 9.

Further, in accordance with embodiments of the present invention, ion implantation and laser annealing are separate processes. Therefore, the substrate temperature can be maintained at a predetermined level from before the laser irradiation is performed. As a result, the spread of characteristics of IGBTs formed on the FZ-N substrate 1 can be reduced. As a result, the quality ratio of FS-type IGBT 100 can be increased.

The contents of Embodiment 1 and the example can be summarized as follows.

(1) The following laser annealing conditions are preferred: irradiation energy density of the laser light 14 with a range of 1.2 J/cm² to 4 J/cm², and the substrate temperature within a range of 100° C. to 500° C.

(2) When laser annealing is performed only with a solid state laser such as a YAG 2ω laser, without using a combination with a semiconductor laser, the irradiation energy density of the laser light 14 may be within a range from 1.2 J/cm² to 4 J/cm² and the substrate temperature may be within a range of 200° C. to 500° C., the irradiation energy density of the laser light may be within a range of 2.6 J/cm² to 4 J/cm², and the substrate temperature may be within a range of 300° C. to 500° C. (see FIG. 6).

(3) Where a solid state laser such as a YAG 2ω laser is combined with a semiconductor laser and when a plurality of solid state lasers such as YAG 2ω lasers are used, with a irradiation energy density of 4 J/cm², the substrate temperature may be within a range of 100° C. to 500° C. A substrate temperature within a range of 200° C. to 500° C. is preferred (see FIG. 7).

(4) The wavelength of the laser light is preferably within a range of 200 nm to 900 nm.

(5) By implementing the features (1) to (4), it is possible to obtain the desired diffusion profile.

In the present example, the FS-type IGBT is explained, but such selection is not limiting. For example, the present invention can be also applied to the formation of a p⁺ collector layer of a NPT-type IGBT, a p⁺ collector layer of a reverse blocking IGBT, an n drain layer of a power MOSFET and also to the formation of a back face diffusion layer of a power IC (a high-concentration diffusion layer for ensuring ohmic contact with the back face electrode). The effect demonstrated in such applications is similar to that obtained with the aforementioned FS-type IGBT.

As described hereinabove, according to Embodiment 1, where the substrate is heated during activation of the ion implantation layer (p⁺ collector layer 10 and FS layer 9), the ion implantation layer is more easily activated under the effect of heating. Because laser irradiation is performed, the effect of heat on activation is increased and activation is facilitated with respect to that in the case of laser annealing performed from the room temperature. An especially significant effect of heating the substrate is produced on layers that are deep into the laser irradiation face because the heat of laser radiation is unlikely to penetrate thereto. This allows effective activation of the FS layer 9. Further, crystal defects in the ion implantation layer can be sufficiently repaired. The resulting effect is that the desired diffusion profile can be obtained with a small spread. In addition, since the temperature of the front face structure is controlled to be less than or equal to 500° C. during laser annealing, fewer adverse effects, such as oxidation, melting, etc., are produced on the emitter electrode. Therefore, it is possible to increase the activation ratio of the dopants that have been ion implanted into the back face, without adversely affecting the front face structure of the device.

### Embodiment 2

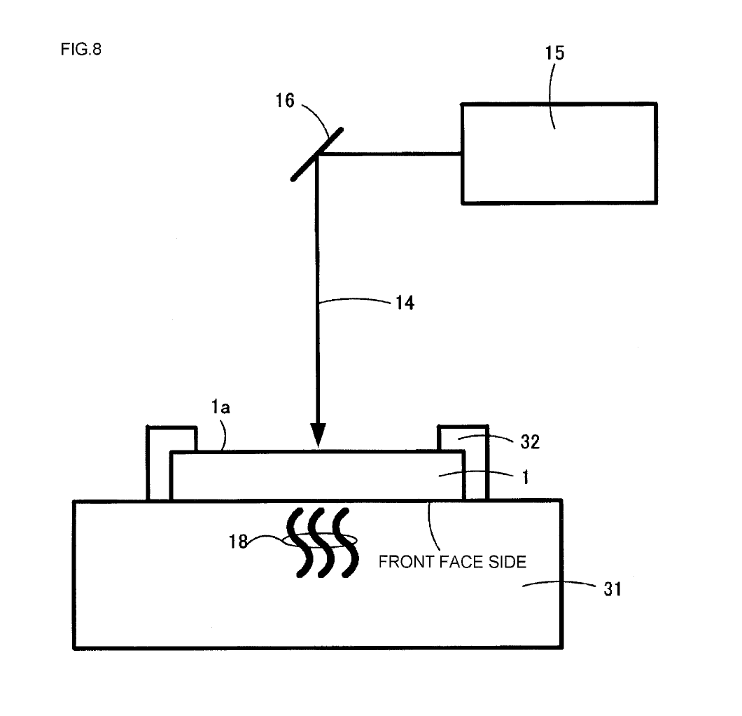

FIG. 8 is a configuration diagram illustrating the principal portion of the apparatus for manufacturing a semiconductor device according to Embodiment 2. In the manufacturing apparatus shown in FIG. 8, laser annealing is performed to activate the ion-implanted dopants. This manufacturing apparatus is constituted by the laser irradiation unit 15, the optical system mirror 16 guiding the laser light 14 to the FZ-N substrate 1 (wafer), the substrate heating unit 31 that heats the FZ-N substrate 1, and a guide 32 (claw) fixing the FZ-N substrate 1 to the substrate heating unit 31. For example, the manufacturing apparatus shown in FIG. 8 can be used for manufacturing the semiconductor device according to Embodiment 1. By arranging the guide 32 that fixes the FZ-N substrate 1 to the substrate heating unit 31, it is possible to realize both a support unit for supporting the FZ-N substrate 1 and a heating unit for heating the FZ-N substrate 1.

With the manufacturing apparatus shown in FIG. 8, laser annealing can be performed by laser beam irradiation, while heating the substrate. For example, the substrate heating unit 31 can be a hot plate that enables temperature control with the guide 32 for fixing the FZ-N substrate 1 attached to the substrate heating unit 31. It is preferred that a 4-mm zone at the outer circumference of the substrate (wafer) be fixed during heating of the substrate to prevent the FZ-N substrate 1 from warping up under the effects of heating.

The substrate heating unit may not only be the above-described hot plate, but also a hot air blowing unit that blows hot air on the substrate or a far-IR radiation emitting unit that heats the substrate by radiating thermal radiation. These hot air blowing unit and far-IR radiation emitting unit are means for heating the substrate. An electrostatic chuck or a vacuum chuck that has been used in the usual laser annealing apparatus can also be used as a unit for supporting the substrate during heating.

The manufacturing apparatus shown in FIG. 8 is a laser annealing apparatus equipped with a hot plate for heating the substrate and does not includes an ion implantation unit, such as the manufacturing apparatus described in Patent Document 1. Therefore, the manufacturing apparatus can be greatly reduced in size. Furthermore, by using the laser annealing apparatus equipped with the substrate heating unit, it is possible to sufficiently activate the dopants that have been ion implanted in the back face of the substrate within a short time period, without using the usual, more expensive electric furnace, which reduces production costs.

As described hereinabove, in accordance with Embodiment 2, by using the laser annealing apparatus equipped with the substrate heating unit 31, it is possible to perform sufficient activation, even without using the usual electric furnace. Therefore, an apparatus for manufacturing a semiconductor device that enables a high degree of activation can be provided at a low cost. Furthermore, the production costs can be reduced because it is not necessary to use the usual electric furnace (diffusion furnace or the like), which is more expensive than the substrate heating unit (hot plate) 31.

The embodiment of the present invention are explained hereinabove by considering a FS-type IGBT as an example, but the above-described embodiment is not limiting, and the present invention can be also applied to a power IC (integrated circuit), and a MOSFET (MOS gate field effect transistor). Further, a configuration can be also used in which n and p types are all inverted.

As described hereinabove, the methods for manufacturing a semiconductor device in accordance with embodiments of the present invention are suitable for manufacturing semiconductor devices such as power IC, MOSFET, and IGBT.

The following is an explanation of reference numerals used herein:
1 FZ-N substrate (after thickness reduction)
1a back face
1b FZ-N substrate (before thickness reduction)
2 gate oxidation film
3 gate electrode
4 p⁺ base layer
5 n⁺ emitter layer
6 interlayer insulating film
7 emitter electrode (front face electrode)
8 front face structure
9 FS layer (n⁺ field stop layer)
9a n⁺ layer
10 p⁺ collector layer
10a p⁺ layer
11 back face electrode (collector electrode)
12 ion implantation of phosphorus
13 ion implantation of boron
14 laser light
15 laser irradiation unit
16 optical system mirror
17 electrostatic chuck
18 heat
21 n⁻ active layer
22 p⁺ collector layer
24 separation layer
31 substrate heating unit
32 guide
100 FS-type IGBT
101 direction, parallel to the surface of the FZ-N substrate
102 region (laser annealed chip)
103 region (chip has not been laser annealed)

What is claimed is:

1. A method for manufacturing a semiconductor device, the method comprising:
forming a front face structure of a semiconductor device on a first main face of a semiconductor substrate;
grinding a second main face of the semiconductor substrate and reducing the semiconductor substrate in thickness to a thickness equal to or less than 100 μm;
ion implanting a dopant into the second main face of the semiconductor substrate of reduced thickness; and
activating the dopant by irradiating the second main face with laser light and performing laser annealing in a state in which the semiconductor substrate of reduced thickness is heated, wherein
a heating temperature of the semiconductor substrate is 100° C. to 500° C.,
a wavelength of the laser light used in the laser annealing is 200 nm to 900 nm,
an irradiation energy density of the laser light is 1.2 J/cm² to 4 J/cm²,
the laser light is constituted by YAG 2ω laser light and semiconductor laser light, and
irradiation with the YAG 2ω laser light and the semiconductor laser light is performed simultaneously.

2. A method for manufacturing a semiconductor device, the method comprising:
forming a front face structure of a semiconductor device on a first main face of a semiconductor substrate;
grinding a second main face of the semiconductor substrate and reducing the semiconductor substrate in thickness to a thickness equal to or less than 100 μm;
ion implanting a dopant into the second main face of the semiconductor substrate of reduced thickness; and
activating the dopant by irradiating the second main face with laser light and performing laser annealing in a state in which the semiconductor substrate of reduced thickness is heated, wherein
a heating temperature of the semiconductor substrate is 100° C. to 500° C.,
a wavelength of the laser light used in the laser annealing is 200 nm to 900 nm,
an irradiation energy density of the laser light is 1.2 J/cm² to 4 J/cm², and
the laser light is radiated from two YAG 2ω lasers and the laser light is radiated as 100 ns pulses with a spacing of 500 ns.
